(19) United States
(12) Patent Application Publication
(10) Pub. No.: US 2022/0049342 A1
(43) Pub. Date: Feb. 17, 2022

(54) MASK AND FABRICATING METHOD THEREOF, AND DISPLAYING BASE PLATE AND FABRICATING METHOD THEREOF

(71) Applicants: Chongqing BOE Display Technology Co., Ltd., Chongqing (CN); BOE Technology Group Co., Ltd., Beijing (CN)

(72) Inventors: Wei Zhang, Beijing (CN); Hui Li, Beijing (CN); Shicheng Sun, Beijing (CN); Jonguk Kwak, Beijing (CN); Xinwei Wu, Beijing (CN); Cunzhi Li, Beijing (CN)

(73) Assignees: Chongqing BOE Display Technology Co., Ltd., Chongqing (CN); BOE Technology Group Co., Ltd., Beijing (CN)

(21) Appl. No.: 17/185,247

(22) Filed: Feb. 25, 2021

(30) Foreign Application Priority Data
Aug. 11, 2020 (CN) 202010801545.8

(51) Int. Cl. C23C 14/04; H01L 51/00

(52) U.S. Cl. CPC C23C 14/042; H01L 51/0011; H01L 51/0097

(57) ABSTRACT

A mask and a fabricating method thereof, and a displaying base plate and a fabricating method thereof, which relates to the technical field of displaying. The mask includes at least one mask unit, and the at least one mask unit includes an opening region and a main-body region that surrounds the opening region; and the main-body region includes a via-hole unit adjacent to the opening region, and the via-hole unit is configured so that, when the mask is being used on a substrate to form a film-layer pattern, a film-layer material is able to pass through the via-hole unit and deposit within a region of the substrate that corresponds to the opening region. The present disclosure is suitable for the fabrication of masks.

### CROSS REFERENCE TO RELEVANT APPLICATIONS

The present disclosure claims the priority of the Chinese patent application filed on Aug. 11, 2020 before the Chinese Patent Office with the application number of 202010801545.8 and the title of “MASK AND FABRICATING METHOD THEREOF, AND DISPLAYING BASE PLATE AND FABRICATING METHOD THEREOF”, which is incorporated herein in its entirety by reference.

### TECHNICAL FIELD

The present disclosure relates to the technical field of displaying, and particularly relates to a mask and a fabricating method thereof, and a displaying base plate and a fabricating method thereof.

### BACKGROUND

Active matrix organic light emitting diode (AMOLED) display panels have the characteristic of self-Illumination, and do not require a backlight module, and, therefore, as compared with liquid-crystal display panels, they can be made thinner. Moreover, AMOLED display panels also have characteristics such as a large field angle, a high refresh rate and a high contrast, and thus are increasingly more popular in the market.

In the fabrication of an AMOLED display panel, an opening mask (Open Mask) is used to perform film-layer vapor deposition or deposition of the inorganic layer.

### SUMMARY

The embodiments of the present disclosure provide a mask and a fabricating method thereof, and a displaying base plate and a fabricating method thereof.

In an aspect, there is provided a mask, wherein the mask comprises at least one mask unit, and the at least one mask unit comprises an opening region and a main-body region that surrounds the opening region; and

the main-body region comprises a via-hole unit adjacent to the opening region, and the via-hole unit is configured so that, when the mask is being used on a substrate to form a film-layer pattern, a film-layer material is able to pass through the via-hole unit and deposit within a region of the substrate that corresponds to the opening region.

Optionally, the mask is made from a metal.

Optionally, the via-hole unit comprises a first via hole and a second via hole that are connected alternatingly in a direction perpendicular to the mask, wherein a distance from the second via hole to an edge of the opening region is less than a distance from the first via hole to the edge of the opening region.

Optionally, a range of the distance from the first via hole to the edge of the opening region is 50-100 μm.

Optionally, the via-hole unit comprises an oblique hole, an included angle between a center line of the oblique hole and a plane where the mask is located is less than 90 degrees, the oblique hole comprises a first opening end and a second opening end, and a distance from the second opening end to an edge of the opening region is less than a distance from the first opening end to the edge of the opening region.

Optionally, a range of the distance from the first opening end to the edge of the opening region is 50-100 μm.

Optionally, the oblique hole is formed by laser etching.

Optionally, a cross-sectional shape of the opening region that is parallel to the mask is rectangular; and

all of four sides of the opening region are provided with one instance of the via-hole unit.

Optionally, the via-hole units located on the four sides of the opening region are not connected.

Optionally, the main-body region comprises a half-etched region and a reserved region that is connected to the half-etched region;

a thickness in a direction perpendicular to the mask of a part of the mask that is located at the half-etched region is less than a thickness in the direction perpendicular to the mask of a part of the mask that is located at the reserved region; and

the via-hole unit is located at the half-etched region.

Optionally, a range of the thickness in the direction perpendicular to the mask of the part of the mask that is located at the half-etched region is 25-75 μm, and a range of the thickness in the direction perpendicular to the mask of the part of the mask that is located at the reserved region is 80-150 μm.

In another aspect, there is provided a displaying base plate, wherein the displaying base plate comprises: a substrate and a film-layer pattern that is formed on the substrate, and the film-layer pattern is formed by using the mask stated above.

Optionally, the substrate is a rigid substrate or a flexible substrate.

In yet another aspect, there is provided a method for fabricating the mask stated above, wherein the mask comprises at least one mask unit, and the at least one mask unit comprises an opening region and a main-body region that surrounds the opening region; and

the method comprises:

forming, at the main-body region, a via-hole unit adjacent to the opening region, wherein the via-hole unit is configured so that, when the mask is being used on a substrate to form a film-layer pattern, a film-layer material is able to pass through the via-hole unit and deposit within a region of the substrate that corresponds to the opening region.

Optionally, the via-hole unit comprises a first via hole and a second via hole that are connected alternatingly in a direction perpendicular to the mask; and

the step of forming, at the main-body region, the via-hole unit adjacent to the opening region comprises:

forming, by dry etching or wet etching, the first via hole and the second via hole that are connected alternatingly in the direction perpendicular to the mask, wherein a distance from the second via hole to an edge of the opening region is less than a distance from the first via hole to the edge of the opening region.

Optionally, the via-hole unit comprises an oblique hole; and

the step of forming, at the main-body region, the via-hole unit adjacent to the opening region comprises:

forming the oblique hole by laser etching, wherein an included angle between a center line of the oblique hole and a plane where the mask is located is less than 90 degrees, the oblique hole comprises a first opening end and a second opening end, and a distance from the second opening end to an edge of the opening region is less than a distance from the first opening end to the edge of the opening region.

Optionally, the main-body region comprises a half-etched region and a reserved region that is connected to the half-etched region;

before the step of forming, at the main-body region, the via-hole unit adjacent to the opening region, the method further comprises:

forming, by half etching, the mask having different thicknesses, wherein a thickness in a direction perpendicular to the mask of a part of the mask that is located at the half-etched region is less than a thickness in the direction perpendicular to the mask of a part of the mask that is located at the reserved region; and

the step of forming, at the main-body region, the via-hole unit adjacent to the opening region comprises:

forming, at the half-etched region, the via-hole unit adjacent to the opening region.

In still another aspect, there is provided a method for fabricating a displaying base plate, wherein the method comprises:

providing a film forming substrate;

providing the mask stated above;

aligning the film forming substrate and the mask, whereby the opening region of the mask corresponds to a film forming region of the film forming substrate and the main-body region of the mask corresponds to a no-film-formation region of the film forming substrate; and

forming the film-layer pattern on the film forming substrate by using the mask.

Optionally, the via-hole unit of the mask comprises a first via hole and a second via hole that are connected alternatingly in a direction perpendicular to the mask, wherein a distance from the second via hole to an edge of the opening region is less than a distance from the first via hole to the edge of the opening region; and

the step of aligning the film forming substrate and the mask, whereby the opening region of the mask corresponds to the film forming region of the film forming substrate and the main-body region of the mask corresponds to the no-film-formation region of the film forming substrate comprises:

aligning the film forming substrate and the mask, whereby the second via hole of the mask faces the film forming substrate and the opening region of the mask corresponds to the film forming region of the film forming substrate and the main-body region of the mask corresponds to the no-film-formation region of the film forming substrate.

Optionally, the via-hole unit of the mask comprises an oblique hole, an included angle between a center line of the oblique hole and a plane where the mask is located is less than 90 degrees, the oblique hole comprises a first opening end and a second opening end, and a distance from the second opening end to an edge of the opening region is less than a distance from the first opening end to the edge of the opening region; and

the step of aligning the film forming substrate and the mask, whereby the opening region of the mask corresponds to the film forming region of the film forming substrate and the main-body region of the mask corresponds to the no-film-formation region of the film forming substrate comprises:

aligning the film forming substrate and the mask, whereby the second opening end of the mask faces the film forming substrate and the opening region of the mask corresponds to the film forming region of the film forming substrate and the main-body region of the mask corresponds to the no-film-formation region of the film forming substrate.

The above description is merely a summary of the technical solutions of the present disclosure. In order to more clearly know the elements of the present disclosure to enable the implementation according to the contents of the description, and in order to make the above and other purposes, features and advantages of the present disclosure more apparent and understandable, the particular embodiments of the present disclosure are provided below.

### BRIEF DESCRIPTION OF THE DRAWINGS

In order to more clearly illustrate the technical solutions of the embodiments of the present disclosure or the related art, the figures that are required to describe the embodiments or the related art will be briefly introduced below. Apparently, the figures that are described below are merely embodiments of the present disclosure, and a person skilled in the art can obtain other figures according to these figures without paying creative work.

FIG. 1 is a schematic structural diagram of the fabrication of a film-layer pattern by using an opening mask in the related art;

FIG. 2 is a schematic structural diagram of the mask according to an embodiment of the present disclosure;

FIG. 3 is a cross-sectional view along the EF in FIG. 2;

FIG. 4 is a schematic structural diagram of the fabrication of a film-layer pattern by using the mask shown in FIG. 3;

FIG. 5 is another cross-sectional view along the EF in FIG. 2;

FIG. 6 is a schematic structural diagram of the fabrication of a film-layer pattern by using the mask shown in FIG. 5;

FIG. 7 is yet another cross-sectional view along the EF in FIG. 2;

FIG. 8 is a schematic structural diagram of the fabrication of a film-layer pattern by using the mask shown in FIG. 7; and

FIG. 9 is a schematic structural diagram of the mask comprising a half-etched region and a reserved region according to an embodiment of the present disclosure.

### DETAILED DESCRIPTION

In order to make the objects, the technical solutions and the advantages of the embodiments of the present disclosure clearer, the technical solutions of the embodiments of the present disclosure will be clearly and completely described below with reference to the drawings of the embodiments of the present disclosure. Apparently, the described embodiments are merely certain embodiments of the present disclosure, rather than all of the embodiments. All of the other embodiments that a person skilled in the art obtains on the basis of the embodiments of the present disclosure without paying creative work fall within the protection scope of the present disclosure.

In the embodiments of the present disclosure, terms such as “first” and “second” are used to distinguish identical items or similar items that have substantially the same functions and effects, merely in order to clearly describe the technical solutions of the embodiments of the present disclosure, and should not be construed as indicating or implying the degrees of importance or the quantity of the specified technical features.

In the embodiments of the present disclosure, the meaning of “at least one” is one or more, unless explicitly and clearly defined otherwise.

In the embodiments of the present disclosure, the terms that indicate orientation or position relations, such as “upper” and “lower”, are based on the orientation or position relations shown in the drawings, and are merely for conveniently describing the present disclosure and simplifying the description, rather than indicating or implying that the device or element must have the specific orientation and be constructed and operated according to the specific orientation. Therefore, they should not be construed as a limitation on the present disclosure.

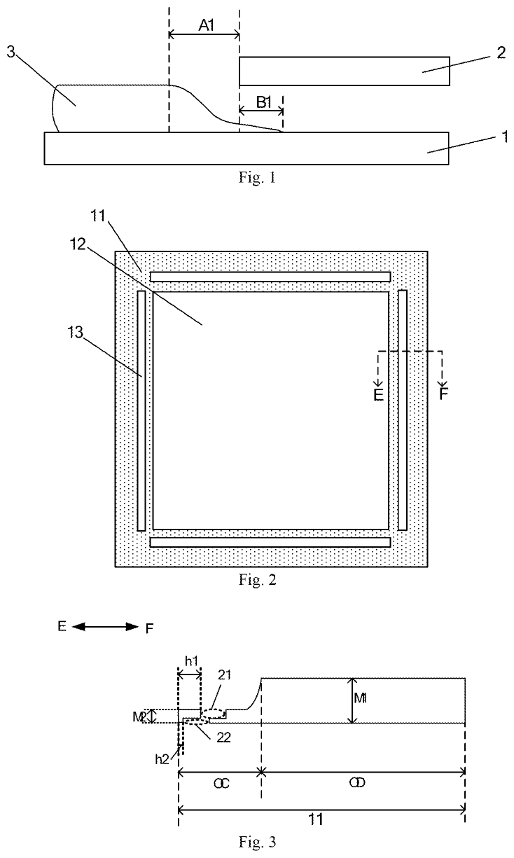

In the fabrication of an AMOLED display panel, an opening mask (Open Mask) is used to perform film-layer vapor deposition or deposition of the inorganic layer. However, referring to FIG. 1, when a second opening mask (Open Mask2) is used to form an inorganic film-layer pattern 3 on a substrate 1, shadow effect will happen at the edge of the Open Mask2, which results in that an inner shadow A and an outer shadow B appear at the inorganic film-layer pattern 3, thereby deteriorating the quality of the fabrication of the inorganic film-layer pattern 3, and in turn affecting the product quality.

An embodiment of the present disclosure provides a mask. The mask comprises at least one mask unit. Referring to FIG. 2, the at least one mask unit comprises an opening region 12 and a main-body region 11 that surrounds the opening region 12.

The main-body region 11 comprises a via-hole unit 13 adjacent to the opening region 12. The via-hole unit is configured so that, when the mask is being used on a substrate to form a film-layer pattern, a film-layer material is able to pass through the via-hole unit and deposit within a region of the substrate that corresponds to the opening region.

The mask is an opening mask (Open Mask), and is mainly applied to AMOLED display products, wherein the mask material of the opening region and the via-hole unit is removed, and the mask material of the main-body region except for the via-hole unit is reserved. The material of the mask is not limited herein. As an example, the mask material may be a metal.

The shape of the opening region of the mask unit is not limited herein. Its cross-sectional shape parallel to the mask may be rectangular, as shown in FIG. 2, and may also be circular, square and so on, which may be determined according to the shape of the film-layer pattern in practice.

The shape of the via-hole unit is not limited herein. The cross-sectional shape of the via-hole unit parallel to the mask may be rectangular, as shown in FIG. 2, and may also be circular and so on. The via-hole unit may be provided on merely one side of the opening region, and may also be provided on a plurality of sides of the opening region. If the cross-sectional shape of the opening region of the mask unit parallel to the mask is rectangular, as shown in FIG. 2, then the via-hole units may be provided on all of the four sides of the opening region, as shown in FIG. 2.

When the mask is being used to form the film-layer pattern on the substrate, the film-layer material is able to pass through the via-hole unit of the main-body region and deposit within the region of the substrate that corresponds to the opening region, which increases the amount of the film-material deposition at the edge of the film-layer pattern, thereby effectively reducing the size of the inner shadow, in turn improving the quality of the fabrication of the film-layer pattern, and finally improving the product quality.

Two particular structures of the via-hole unit will be provided below.

In the first structure, referring to FIGS. 3 and 5, the via-hole unit comprises a first via hole 21 and a second via hole 22 that are connected alternatingly in the direction perpendicular to the mask, and the distance h2 from the second via hole 22 to the edge of the opening region is less than the distance h1 from the first via hole 21 to the edge of the opening region.

The process for fabricating the first via hole and the second via hole is not limited herein. As an example, the first via hole and the second via hole may be formed by dry etching or wet etching.

The range of the distance h1 from the first via hole 21 to the edge of the opening region may be 50-100 μm. For example, the h1 may be 50 μm, 60 μm, 70 μm, 80 μm, 90 μm and so on.

The hole depth of the first via hole in the direction perpendicular to the mask and the hole depth of the second via hole in the direction perpendicular to the mask may be the same or different, which is not limited herein.

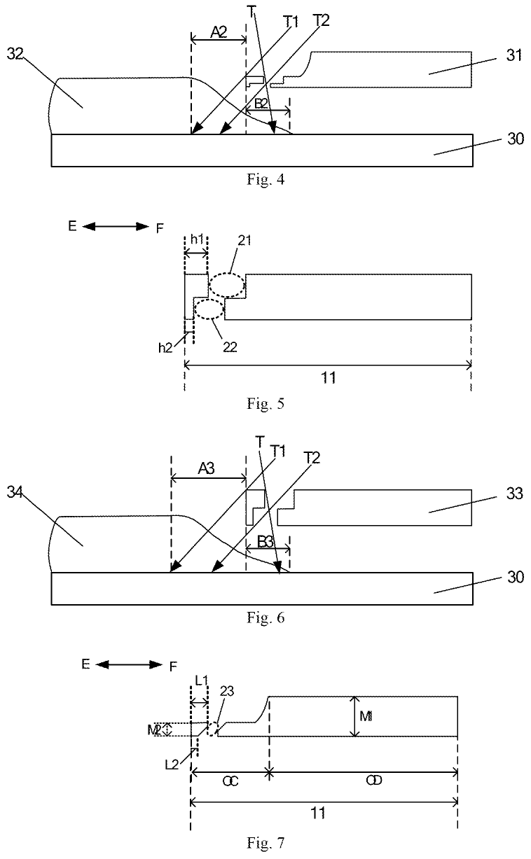

Referring to FIG. 4, when the mask 31 shown in FIG. 3 is being used to form a film-layer pattern 32 on the film forming substrate 30, the film-layer material (for example, a plasma material) may deposit onto the film forming substrate 30 in the direction shown by the arrow straight line T1, and, because the mask is provided with the via-hole unit, the film-layer material may also, in the direction shown by the arrow straight line T2, pass through the first via hole and the second via hole and deposit onto the film forming substrate 30, which increases the amount of the film-material deposition at the edge of the film-layer pattern, thereby effectively reducing the size of the inner shadow, and improving the uniformity of the inner shadow. In FIG. 4, the distance A2 from the edge of the main-body region of the mask to the 90%-thickness line (90% THK) of the film-layer pattern is the width of the inner shadow, wherein the 90%-thickness line is perpendicular to the film forming substrate and the thickness of the film-layer pattern of the area where it is located is 90% of the preset thickness of the mask layer, and the distance B2 from the orthographic projection of the edge of the main-body region of the mask on the film forming substrate 30 to the edge of the film-layer pattern that is located under the main-body region of the mask is the width of the outer shadow.

In the same manner, referring to FIG. 6, when the mask 33 shown in FIG. 5 is being used to form a film-layer pattern 34 on the film forming substrate 30, the film-layer material (for example, a plasma material) may deposit onto the film forming substrate 30 in the direction shown by the arrow straight line T1, and, because the mask is provided with the via-hole unit, the film-layer material may also, in the direction shown by the arrow straight line T2, pass through the first via hole and the second via hole and deposit onto the film forming substrate 30, which increases the amount of the film-material deposition at the edge of the film-layer pattern, thereby effectively reducing the size of the inner shadow, and improving the uniformity of the inner shadow. In FIG. 6, the width of the inner shadow is A3, and the width of the outer shadow is B3.

It should be noted that, referring to FIGS. 4 and 6, the film-layer material also deposits in the reverse direction (in the direction shown by the arrow straight line T) onto the substrate located under the main-body region of the mask, but, because the first via hole 21 and the second via hole 22 are connected alternatingly in the direction perpendicular to the mask, and the distance h2 from the second via hole 22 to the edge of the opening region is less than the distance h1 from the first via hole 21 to the edge of the opening region, merely the film-layer material that moves in a direction that forms a large included angle with the substrate can pass through the first via hole and the second via hole. By adjusting the distance h1 from the first via hole to the edge of the opening region, such a part of the film-layer material can deposit within the area of the original outer shadow, and the width of the outer shadow is not increased.

In the second structure, referring to FIG. 7, the via-hole unit comprises an oblique hole 23, the included angle between the center line of the oblique hole and the plane where the mask is located is less than 90 degrees, the oblique hole comprises a first opening end (not shown in FIG. 7) and a second opening end (not shown in FIG. 7), and the distance L2 from the second opening end to the edge of the opening region is less than the distance L1 from the first opening end to the edge of the opening region. In FIG. 7, the first opening end of the oblique hole is the upper opening end, and the second opening end is the lower opening end.

The range of the distance L1 from the first opening end to the edge of the opening region may be 50-100 μm. For example, the L1 may be 50 μm, 60 μm, 70 μm, 80 μm, 90 μm and so on.

The process for fabricating the oblique hole is not limited herein. As an example, the oblique hole may be formed by laser etching.

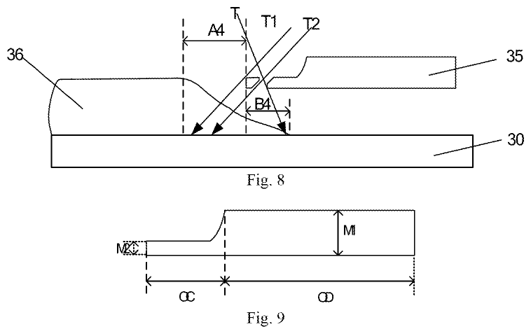

Referring to FIG. 8, when the mask 35 shown in FIG. 7 is being used to form a film-layer pattern 36 on the film forming substrate 30, the film-layer material (for example, a plasma material) may deposit onto the film forming substrate 30 in the direction shown by the arrow straight line T1, and, because the mask is provided with the via-hole unit, the film-layer material may also, in the direction shown by the arrow straight line T2, pass through the oblique hole and deposit onto the film forming substrate 30, which increases the amount of the film-material deposition at the edge of the film-layer pattern, thereby effectively reducing the size of the inner shadow, and improving the uniformity of the inner shadow. In FIG. 8, the width of the inner shadow is A4, and the width of the outer shadow is B4.

It should be noted that, referring to FIG. 8, the film-layer material also deposits in the reverse direction (in the direction shown by the arrow straight line T) onto the substrate located under the main-body region of the mask, but, because the included angle between the center line of the oblique hole and the plane where the mask is located is less than 90 degrees, the oblique hole comprises a first opening end and a second opening end, and the distance L2 from the second opening end to the edge of the opening region is less than the distance L1 from the first opening end to the edge of the opening region, merely the film-layer material that moves in a direction that forms a large included angle with the substrate can pass through the oblique hole. By adjusting the distance L1 from the first opening end to the edge of the opening region, such a part of the film-layer material can deposit within the area of the original outer shadow, and the width of the outer shadow is not increased.

Optionally, in order to further reduce the size of the inner shadow, referring to FIG. 2, the cross-sectional shape of the opening region 12 that is parallel to the mask is rectangular, and all of the four sides of the opening region 12 are provided with a via-hole unit 13.

If all of the via-hole units located on the four sides of the opening region are connected, the main-body parts between the via-hole units and the opening region are separated from the main-body parts located on the sides of the via-hole units that are further away from the opening region, which increases the difficulty in the fixing of the mask, and is adverse to the usage of the mask. In order to prevent that, further optionally, referring to FIG. 2, the via-hole units 13 located on the four sides of the opening region 12 are not connected.

Optionally, referring to FIGS. 3 and 7, the main-body region 11 comprises a half-etched region OC and a reserved region OD that is connected to the half-etched region OC; the thickness M2 in the direction perpendicular to the mask of the part of the mask that is located at the half-etched region OC is less than the thickness M1 in the direction perpendicular to the mask of the part of the mask that is located at the reserved region OD; and the via-hole unit is located at the half-etched region.

The range of the thickness M2 in the direction perpendicular to the mask of the part of the mask that is located at the half-etched region OC may be 25-75 μm. For example, the M2 may be 30 μm, 40 μm, 50 μm, 60 μm, 70 μm and so on. The range of the thickness M1 in the direction perpendicular to the mask of the part of the mask that is located at the reserved region OD may be 50-150 μm. For example, the M1 may be 60 μm, 80 μm, 100 μm, 110 μm, 120 μm and so on.

Referring to FIG. 3, the first via hole 21 and the second via hole 22 of the via-hole unit are located at the half-etched region OC. Referring to FIG. 7, the oblique hole 23 of the via-hole unit is located at the half-etched region OC.

The half-etched region OC and the reserved region OD shown in FIG. 9 may be formed by half etching, and then the half-etched region OC is continually etched, by controlling the etching process parameters (for example, the etching speed, the etching duration and so on), thereby forming via-hole units comprising different structures.

The via-hole unit is provided at the half-etched region, and the thickness in the direction perpendicular to the mask of the part of the mask that is located at the half-etched region is less than the thickness in the direction perpendicular to the mask of the part of the mask that is located at the reserved region. Accordingly, when the mask is being used to form the film-layer pattern on the film forming substrate, the thickness of the via-hole unit in the direction perpendicular to the mask is reduced, which facilitates the film-layer material to pass through the via-hole unit and deposit onto the film forming substrate, to further increase the amount of the film-material deposition at the edge of the film-layer pattern, thereby further reducing the size of the inner shadow.

An embodiment of the present disclosure provides a displaying base plate, wherein the displaying base plate comprises: a substrate and a film-layer pattern that is formed on the substrate, and the film-layer pattern is formed by using the mask according to the above embodiments.

The film-layer pattern may be formed by using the mask by vapor deposition, and may also be formed by using the mask by another deposition process. The material of the film-layer pattern is not limited, and it may be an inorganic material, which is used to form a packaging layer, to package an active matrix organic light emitting diode (AMOLED). The substrate may be a rigid substrate, for example, a glass substrate, and may also be a flexible substrate, for example, a polyimide (PI) film.

It should be noted that the displaying base plate may also comprise other structures, such as a thin-film transistor, a grid line and a data line, and merely the contents that are relative to the inventiveness are described herein.

The displaying base plate has the advantages of a high quality of the film-layer pattern and a high product quality, and is mainly used in AMOLED display devices and any products or components having a displaying function that comprise those AMOLED display devices, such as a television set, a digital camera, a mobile phone and a tablet personal computer.

An embodiment of the present disclosure provides a method for fabricating the mask according to the above embodiments. Referring to FIG. 2, the mask unit comprises an opening region 12 and a main-body region 11 that surrounds the opening region 12.

The method comprises:

S10: forming, at the main-body region, a via-hole unit adjacent to the opening region, wherein the via-hole unit is configured so that, when the mask is being used on a substrate to form a film-layer pattern, a film-layer material is able to pass through the via-hole unit and deposit within a region of the substrate that corresponds to the opening region.

When the mask formed by using the above method is being used to form the film-layer pattern on the substrate, the film-layer material is able to pass through the via-hole unit of the main-body region and deposit within the region of the substrate that corresponds to the opening region, which increases the amount of the film-material deposition at the edge of the film-layer pattern, thereby effectively reducing the size of the inner shadow, in turn improving the quality of the fabrication of the film-layer pattern, and finally improving the product quality.

Optionally, referring to FIGS. 3 and 5, the via-hole unit comprises a first via hole 21 and a second via hole 22 that are connected alternatingly in the direction perpendicular to the mask.

The step S10 of forming, at the main-body region, the via-hole unit adjacent to the opening region comprises:

forming, by dry etching or wet etching, the first via hole and the second via hole that are connected alternatingly in the direction perpendicular to the mask, wherein, referring to FIGS. 3 and 5, the distance h2 from the second via hole 22 to the edge of the opening region is less than the distance h1 from the first via hole 21 to the edge of the opening region.

The fabricating method is simple and easy to implement, and has a good operability.

Optionally, referring to FIG. 7, the via-hole unit comprises an oblique hole 23.

The step S10 of forming, at the main-body region, the via-hole unit adjacent to the opening region comprises:

forming the oblique hole by laser etching, wherein an included angle between a center line of the oblique hole and a plane where the mask is located is less than 90 degrees, the oblique hole comprises a first opening end and a second opening end, and, referring to FIG. 7, the distance L2 from the second opening end to the edge of the opening region is less than the distance L1 from the first opening end to the edge of the opening region.

By controlling the process parameters such as the direction and the magnitude of the laser and the etching duration, the oblique hole can be formed.

Further optionally, referring to FIGS. 3 and 7, the main-body region 11 comprises a half-etched region OC and a reserved region OD that is connected to the half-etched region OC.

Before the step S10 of forming, at the main-body region, the via-hole unit adjacent to the opening region, the method further comprises:

S11: forming, by half etching, the mask having different thicknesses, wherein, referring to FIG. 9, the thickness M2 in the direction perpendicular to the mask of the part of the mask that is located at the half-etched region OC is less than the thickness M1 in the direction perpendicular to the mask of the part of the mask that is located at the reserved region OD.

The step S10 of forming, at the main-body region, the via-hole unit adjacent to the opening region comprises:

forming, at the half-etched region, the via-hole unit adjacent to the opening region.

In the mask formed by using the above method, the via-hole unit is provided at the half-etched region, which further reduces the size of the inner shadow that is generated when the mask is being used to form the film-layer pattern.

The related description on the structure of the mask according to the present embodiment may refer to the above embodiments, which is not discussed here further.

An embodiment of the present disclosure provides a method for fabricating a displaying base plate, wherein the method comprises:

S01: providing a film forming substrate. The material of the film forming substrate is not limited herein. The film forming substrate may be a rigid substrate, for example, a glass substrate, and may also be a flexible substrate, for example, a polyimide (PI) film.

S02: providing the mask according to the above embodiments.

S03: aligning the film forming substrate and the mask, whereby the opening region of the mask corresponds to a film forming region of the film forming substrate and the main-body region of the mask corresponds to a no-film-formation region of the film forming substrate.

S04: forming the film-layer pattern on the film forming substrate by using the mask. The film-layer pattern may be a packaging layer, and may also be another pattern, which is not limited herein.

The fabricating method is simple and easy to implement, and has a good operability.

Optionally, referring to FIGS. 3 and 5, the via-hole unit of the mask comprises a first via hole 21 and a second via hole 22 that are connected alternatingly in the direction perpendicular to the mask, and the distance h2 from the second via hole 22 to the edge of the opening region is less than the distance h1 from the first via hole 21 to the edge of the opening region.

The step S03 of aligning the film forming substrate and the mask, whereby the opening region of the mask corresponds to the film forming region of the film forming substrate and the main-body region of the mask corresponds to the no-film-formation region of the film forming substrate comprises:

aligning the film forming substrate and the mask, whereby the second via hole of the mask faces the film forming substrate and the opening region of the mask corresponds to the film forming region of the film forming substrate and the main-body region of the mask corresponds to the no-film-formation region of the film forming substrate.

Accordingly, that can ensure that, in the film coating, the film-layer material (for example, a plasma gas) can pass through the first via hole and the second via hole of the main-body region and deposit within the film forming region in the film forming substrate, thereby improving the uniformity of the inner shadow, reducing the size of the inner shadow, and improving the product quality.

Optionally, referring to FIG. 7, the via-hole unit comprises an oblique hole 23, the included angle between the center line of the oblique hole and the plane where the mask is located is less than 90 degrees, the oblique hole comprises a first opening end (not shown in FIG. 7) and a second opening end (not shown in FIG. 7), and the distance L2 from the second opening end to the edge of the opening region is less than the distance L1 from the first opening end to the edge of the opening region. In FIG. 5, the first opening end of the oblique hole 23 is the upper opening end, and the second opening end is the lower opening end.

The step S03 of aligning the film forming substrate and the mask, whereby the opening region of the mask corresponds to the film forming region of the film forming substrate and the main-body region of the mask corresponds to the no-film-formation region of the film forming substrate comprises:

aligning the film forming substrate and the mask, whereby the second opening end of the mask faces the film forming substrate and the opening region of the mask corresponds to the film forming region of the film forming substrate and the main-body region of the mask corresponds to the no-film-formation region of the film forming substrate.

Accordingly, that can ensure that, in the film coating, the film-layer material (for example, a plasma gas) can pass through the oblique hole of the main-body region and deposit within the film forming region in the film forming substrate, thereby improving the uniformity of the inner shadow, reducing the size of the inner shadow, and improving the product quality.

The related description on the structure of the mask according to the present embodiment may refer to the above embodiments, which is not discussed here further.

The above are merely particular embodiments of the present disclosure, and the protection scope of the present disclosure is not limited thereto. All of the variations or substitutions that a person skilled in the art can easily envisage within the technical scope disclosed by the present disclosure should fall within the protection scope of the present disclosure. Therefore, the protection scope of the present disclosure should be subject to the protection scope of the claims.

The above-described device embodiments are merely illustrative, wherein the units that are described as separate components may or may not be physically separate, and the components that are displayed as units may or may not be physical units; in other words, they may be located at the same one location, and may also be distributed to a plurality of network units. Part or all of the modules may be selected according to the actual demands to realize the purposes of the solutions of the embodiments. A person skilled in the art can understand and implement the technical solutions without paying creative work.

The “one embodiment”, “an embodiment” or “one or more embodiments” as used herein means that particular features, structures or characteristics described with reference to an embodiment are included in at least one embodiment of the present disclosure. Moreover, it should be noted that here an example using the wording “in an embodiment” does not necessarily refer to the same one embodiment.

The description provided herein describes many concrete details. However, it can be understood that the embodiments of the present disclosure may be implemented without those concrete details. In some of the embodiments, well-known processes, structures and techniques are not described in detail, so as not to affect the understanding of the description.

In the claims, any reference signs between parentheses should not be construed as limiting the claims. The word “comprise” does not exclude elements or steps that are not listed in the claims. The word “a” or “an” preceding an element does not exclude the existing of a plurality of such elements. The present disclosure may be implemented by means of hardware comprising several different elements and by means of a properly programmed computer. In unit claims that list several devices, some of those devices may be embodied by the same item of hardware. The words first, second, third and so on do not denote any order. Those words may be interpreted as names.

Finally, it should be noted that the above embodiments are merely intended to explain the technical solutions of the present disclosure, and not to limit them. Although the present disclosure is explained in detail by referring to the above embodiments, a person skilled in the art should understand that he can still modify the technical solutions set forth by the above embodiments, or make equivalent substitutions to part of the technical features of them. However, those modifications or substitutions do not make the essence of the corresponding technical solutions depart from the spirit and scope of the technical solutions of the embodiments of the present disclosure.

1. A mask, wherein the mask comprises at least one mask unit, and the at least one mask unit comprises an opening region and a main-body region that surrounds the opening region; and
the main-body region comprises a via-hole unit adjacent to the opening region, and the via-hole unit is configured so that, when the mask is being used on a substrate to form a film-layer pattern, a film-layer material is able to pass through the via-hole unit and deposit within a region of the substrate that corresponds to the opening region.

2. The mask according to claim 1, wherein the mask is made from a metal.

3. The mask according to claim 1, wherein the via-hole unit comprises a first via hole and a second via hole that are connected alternatingly in a direction perpendicular to the mask, wherein a distance from the second via hole to an edge of the opening region is less than a distance from the first via hole to the edge of the opening region.

4. The mask according to claim 3, wherein a range of the distance from the first via hole to the edge of the opening region is 50-100 μm.

5. The mask according to claim 1, wherein the via-hole unit comprises an oblique hole, an included angle between a center line of the oblique hole and a plane where the mask is located is less than 90 degrees, the oblique hole comprises a first opening end and a second opening end, and a distance from the second opening end to an edge of the opening region is less than a distance from the first opening end to the edge of the opening region.

6. The mask according to claim 5, wherein a range of the distance from the first opening end to the edge of the opening region is 50-100 μm.

7. The mask according to claim 5, wherein the oblique hole is formed by laser etching.

8. The mask according to claim 1, wherein a cross-sectional shape of the opening region that is parallel to the mask is rectangular; and
all of four sides of the opening region are provided with one instance of the via-hole unit.

9. The mask according to claim 8, wherein the via-hole units located on the four sides of the opening region are not connected.

10. The mask according to claim 1, wherein the main-body region comprises a half-etched region and a reserved region that is connected to the half-etched region;
a thickness in a direction perpendicular to the mask of a part of the mask that is located at the half-etched region is less than a thickness in the direction perpendicular to the mask of a part of the mask that is located at the reserved region; and
the via-hole unit is located at the half-etched region.

11. The mask according to claim 10, wherein a range of the thickness in the direction perpendicular to the mask of the part of the mask that is located at the half-etched region is 25-75 μm, and a range of the thickness in the direction perpendicular to the mask of the part of the mask that is located at the reserved region is 80-150 μm.

12. A displaying base plate, wherein the displaying base plate comprises: a substrate and a film-layer pattern that is formed on the substrate, and the film-layer pattern is formed by using the mask according to claim 1.

13. The displaying base plate according to claim 12, wherein the substrate is a rigid substrate or a flexible substrate.

14. A method for fabricating the mask according to claim 1, wherein the mask comprises at least one mask unit, and the at least one mask unit comprises an opening region and a main-body region that surrounds the opening region; and
the method comprises:
forming, at the main-body region, a via-hole unit adjacent to the opening region, wherein the via-hole unit is configured so that, when the mask is being used on a substrate to form a film-layer pattern, a film-layer material is able to pass through the via-hole unit and deposit within a region of the substrate that corresponds to the opening region.

15. The method according to claim 14, wherein the via-hole unit comprises a first via hole and a second via hole that are connected alternatingly in a direction perpendicular to the mask; and
the step of forming, at the main-body region, the via-hole unit adjacent to the opening region comprises:
forming, by dry etching or wet etching, the first via hole and the second via hole that are connected alternatingly in the direction perpendicular to the mask, wherein a distance from the second via hole to an edge of the opening region is less than a distance from the first via hole to the edge of the opening region.

16. The method according to claim 14, wherein the via-hole unit comprises an oblique hole; and
the step of forming, at the main-body region, the via-hole unit adjacent to the opening region comprises:
forming the oblique hole by laser etching, wherein an included angle between a center line of the oblique hole and a plane where the mask is located is less than 90 degrees, the oblique hole comprises a first opening end and a second opening end, and a distance from the second opening end to an edge of the opening region is less than a distance from the first opening end to the edge of the opening region.

17. The method according to claim 14, wherein the main-body region comprises a half-etched region and a reserved region that is connected to the half-etched region;
before the step of forming, at the main-body region, the via-hole unit adjacent to the opening region, the method further comprises:
forming, by half etching, the mask having different thicknesses, wherein a thickness in a direction perpendicular to the mask of a part of the mask that is located at the half-etched region is less than a thickness in the direction perpendicular to the mask of a part of the mask that is located at the reserved region; and
the step of forming, at the main-body region, the via-hole unit adjacent to the opening region comprises:
forming, at the half-etched region, the via-hole unit adjacent to the opening region.

18. A method for fabricating a displaying base plate, wherein the method comprises:
providing a film forming substrate;
providing the mask according to claim 1;
aligning the film forming substrate and the mask, whereby the opening region of the mask corresponds to a film forming region of the film forming substrate and the main-body region of the mask corresponds to a no-film-formation region of the film forming substrate; and
forming the film-layer pattern on the film forming substrate by using the mask.

19. The method according to claim 18, wherein the via-hole unit of the mask comprises a first via hole and a second via hole that are connected alternatingly in a direction perpendicular to the mask, wherein a distance from the second via hole to an edge of the opening region is less than a distance from the first via hole to the edge of the opening region; and
the step of aligning the film forming substrate and the mask, whereby the opening region of the mask corresponds to the film forming region of the film forming substrate and the main-body region of the mask corresponds to the no-film-formation region of the film forming substrate comprises:
aligning the film forming substrate and the mask, whereby the second via hole of the mask faces the film forming substrate and the opening region of the mask corresponds to the film forming region of the film forming substrate and the main-body region of the mask corresponds to the no-film-formation region of the film forming substrate.

20. The method according to claim 18, wherein the via-hole unit of the mask comprises an oblique hole, an included angle between a center line of the oblique hole and a plane where the mask is located is less than 90 degrees, the oblique hole comprises a first opening end and a second opening end, and a distance from the second opening end to an edge of the opening region is less than a distance from the first opening end to the edge of the opening region; and
the step of aligning the film forming substrate and the mask, whereby the opening region of the mask corresponds to the film forming region of the film forming substrate and the main-body region of the mask corresponds to the no-film-formation region of the film forming substrate comprises:
aligning the film forming substrate and the mask, whereby the second opening end of the mask faces the film forming substrate and the opening region of the mask corresponds to the film forming region of the film forming substrate and the main-body region of the mask corresponds to the no-film-formation region of the film forming substrate.
